(19) United States
(12) Patent Application Publication
(10) Pub. No.: US 2008/0006204 A1
(43) Pub. Date: Jan. 10, 2008

(54) CORROSION RESISTANT WAFER PROCESSING APPARATUS AND METHOD FOR MAKING THEREOF

(75) Inventors: David M. Rusinko, Parma Heights, OH (US); Xiang Liu, Medina, OH (US); Benjamin J. Olechnowicz, Stow, OH (US); Victor L. Lou, Schenectady, NY (US); Jennifer Klug, Strongsville, OH (US)

Correspondence Address: MOMENTIVE PERFORMANCE MATERIALS INC.-Quartz;c/o DILWORTH & BARRESE, LLP, 333 Earle Ovington Blvd., Uniondale, NY, 11553, US

(73) Assignee: General Electric Company, Schenectady, NY (US)

(21) Appl. No.: 11/554,590

(22) Filed: Oct. 31, 2006

Related U.S. Application Data
(60) Provisional application No. 60/806,648, filed on Jul. 6, 2006.

(51) Int. Cl. C23C 14/00; C23C 16/00

(52) U.S. Cl. 118/715; 118/50

(57) ABSTRACT

A wafer processing apparatus characterized by having corrosion resistant connections for its electrical connections, gas feed-through channels, recessed areas, raised areas, MESA, through-holes such as lift-pin holes, threaded bolt holes, blind holes, and the like, with the special configurations employing connectors and fillers having excellent chemical resistant properties and optimized CTEs, i.e., having a coefficient of thermal expansion (CTE) that closely matches the CTE of the base substrate layer, the electrode(s), as well as the CTE of coating layer. In one embodiment, a filler composition comprising a glass-ceramic material is employed.

### CROSS REFERENCE TO RELATED APPLICATION

This application claims the benefits of U.S. 60/806648 filed Jul. 6, 2006, which patent application is fully incorporated herein by reference.

### FIELD OF INVENTION

The invention relates generally to a wafer handling apparatus for use in the manufacture of semiconductors.

### BACKGROUND OF THE INVENTION

The process for fabrication of electronic devices comprises a number of process steps that rely on either the controlled deposition or growth of materials or the controlled and often selective modification of previously deposited/grown materials. Exemplary processes include Chemical Vapor Deposition (CVD), Thermal Chemical Vapor Deposition (TCVD), Plasma Enhanced Chemical Vapor Deposition (PECVD), High Density Plasma Chemical Vapor Deposition (HDP CVD), Expanding Thermal Plasma Chemical Vapor Deposition (ETP CVD), Metal Organic Chemical Vapor Deposition (MOCVD), etc. In some of the processes such as CVD, one or more gaseous reactants are used inside a reactor under low pressure and high temperature conditions to form a solid insulating or conducting layer on the surface of a semiconductor wafer, which is located on a substrate (wafer) holder placed in a reactor.

The substrate holder in the CVD process could function as a heater, which typically contains at least one heating element to heat the wafer; or could function as an electrostatic chuck (ESC), which comprises at least one electrode for electrostatically clamping the wafer; or could be a heater/ESC combination, which has electrodes for both heating and clamping. A substrate holder assembly may include a susceptor for supporting a wafer, and a plurality of heaters disposed under the susceptor to heat the wafer. The semiconductor wafer is heated within a confined environment in a processing vessel at relatively high temperature and often in an atmosphere that is highly corrosive.

After a deposition of a film of predetermined thickness on the semiconductor wafer, there often is spurious deposition on other exposed surfaces inside the reactor. This spurious deposition could present problems in subsequent depositions. It is therefore periodically removed with a cleaning process, i.e. in some cases after every wafer and in other cases after a batch of wafers has been processed. Common cleaning processes in the art include atomic fluorine based cleaning, fluorocarbon plasma cleaning, sulfur hexafluoride plasma cleaning, nitrogen trifluoride plasma cleaning, and chlorine trifluoride cleaning. In the cleaning process, the reactor components, e.g., walls, windows, the substrate holder and assembly, etc., are often corroded/chemically attacked. The corrosion can be extremely aggressive on surfaces that are heated to elevated temperatures, e.g. such as the operating temperature of a typical heater which is typically in the 400-500° C. range but can be as high as the 600-1000° C. range.

A known problem with prior art wafer supports is that electrical connections are typically not corrosion resistant. So even if the heaters, chucks, or susceptors can achieve sufficient lifetime for use in the corrosive, high temperature environment with protective coatings such as AlN, one still needs to circumvent exposure of the contact areas to the corrosive environment. U.S. Pat. No. 6,066,836 discloses a wafer handling apparatus comprising a shaft that contains electrical connections within. The center shaft solution adds stress concentration points to the apparatus, that, when thermally stressed, may crack more easily and thus can further limit the thermal ramp rate or result in shorter useful service life of the apparatus.

U.S. Patent Publication No. 2005/0077284 discloses a wafer holder with electrical leads being housed in ceramic tubular tubes to shield/protect the electrical leads. In this disclosure, glass joint parts or brazing materials, e.g., an organic resin, may be used to connect the tubular tubes with the ceramic substrate. O-rings are employed to hermetically seal the leads in the tubular tubes. Even with the use of O-rings, glass joint parts, brazing materials, etc., it is still expected that the electrodes and leads be exposed to the atmosphere in the chamber. Thus, the use of corrosive gases is not recommended and the apparatus is recommended for low-k film baking.

There is still a need for a wafer processing apparatus with structural components suitable for all semiconductor-processing environments, including those employing corrosive gases. In one embodiment, the invention relates to such a wafer processing apparatus, with electrical contacts and connections designed to be shielded from corrosive gases commonly encountered in semiconductor device processing environments. Furthermore, the apparatus of the invention can withstand the severe thermal stress requirements in semiconductor processing, i.e., high thermal ramp rate of >20° C./min and relatively large temperature differentials of >20° C.

### SUMMARY OF THE INVENTION

In one aspect, the invention relates to a wafer processing apparatus comprising: a base substrate for placing a wafer thereon, the base substrate comprising at least one of graphite, refractory metals, transition metals, rare earth metals and alloys thereof, at least one electrical electrode selected from a resistive heating electrode, a plasma-generating electrode, an electrostatic chuck electrode, and an electron-beam electrode; a lead for connecting the at least one electrical electrode to an external power supply, wherein the lead penetrates the electrode at an interval therefrom; and a filler for filling/sealing the interval between the lead and the electrode; wherein the electrode has a coefficient of thermal expansion (CTE) in a range of 0.75 to 1.25 times that of the substrate respectively.

In another aspect of the invention, the apparatus further comprising at least a coating layer disposed on the electrode, the coating layer comprising at least one of a nitride, carbide, carbonitride, oxynitride of elements selected from a group consisting of B, Al, Si, Ga, Y, refractory hard metals, transition metals, and combinations thereof, wherein the lead penetrates the coating layer and the electrode at an interval therefrom, and the filler for filling/sealing the interval has a CTE in a range of 0.75 to 1.25 times that of the coating layer.

In yet another aspect of the invention, the electrode is embedded in a sintered base substrate, the base substrate comprising a material is selected from the group of oxides, nitrides, carbides, carbonitrides or oxynitrides of elements selected from a group consisting of B, Al, Si, Ga, Y; high thermal stability zirconium phosphates, having the NZP structure of NaZr₂ (PO₄)₃; refractory hard metals; transition metals; oxide and oxynitride of aluminum; and combinations thereof, and optionally a sintering agent.

In one aspect, the lead comprises at least one of molybdenum, nickel, cobalt, iron, tungsten, ruthenium, and alloys thereof. In another aspect, the lead is further coated with one of nickel, oxides or carbides of zirconium, hafnium, cerium, and mixtures thereof.

In one aspect, the apparatus is provided with a plurality of fasteners such as nuts, rivets, bolts, screws, etc., for securing the lead and other functional members to the apparatus, wherein the lead and/or fasteners are coated with an etch-resistant electrically conductive material that is ductile and conforming to the thermal expansion of the component being coated. In one embodiment, the lead and/or fasteners are coated with at least one of nickel, oxides or carbides of zirconium, hafnium, cerium, and mixtures thereof. In yet another aspect, the filler material for use in the wafer processing apparatus to protect/fill the corrosion resistant connections is selected from the group of, a high thermal stability zirconium phosphates, having the NZP structure of NaZr₂ (PO₄)₃; a glass-ceramic composition containing at least one element selected from the group consisting of elements of the group 2a, group 3a and group 4a of the periodic table of element, such as lanthanum aluminosilicate (LAS), magnesium aluminosilicate (MAS), calcium aluminosilicate (CAS), and yttrium aluminosilicate (YAS); a BaO—Al₂O₃—B₂O₃—SiO₂ glass; and a mixture of SiO₂ and a plasma-resistant material comprising an oxide of Y, Sc, La, Ce, Gd, Eu, Dy, or the like, or a fluoride of one of these metals, or yttrium-aluminum-garnet (YAG); and wherein the filler composition has an etch-rate of less than 1000 Angstroms per minute (Å/min) in a processing environment operating at a temperature in a range of 25-600° C.

### BRIEF DESCRIPTION OF THE DRAWINGS

FIG. 1 is a perspective view showing one embodiment of a wafer or substrate treating apparatus.

FIGS. 2A, 2B, and 2C are cross-sectional views of various embodiments of the substrate treating apparatus of FIG. 9, having different layered configurations.

FIG. 3 is a cross-section view of one embodiment of the wafer handling apparatus of the invention.

FIG. 4 is a cross-section view of a second embodiment of the invention, for a wafer processing apparatus with connectors having tapered features.

FIG. 5 is a cross-section view of another embodiment of the invention, for a wafer processing apparatus employing corrosive resistant fillers.

FIG. 6 is a cross-section view of a different embodiment of the wafer processing apparatus with a plurality of electrodes.

FIG. 7 is a cross-section view of a different embodiment of the wafer processing apparatus shown in FIG. 4, with a plurality of electrodes.

FIG. 8 is a cross-section view of a different embodiment of the wafer processing apparatus shown in FIG. 5, with a plurality of electrodes.

FIG. 9 is a cross-section view of a different embodiment of the wafer processing apparatus shown in FIG. 3, with partial removal of the overcoat at the contact areas.

FIG. 10 is a cross-section view of a different embodiment of the wafer processing apparatus shown in FIG. 9, wherein the electrode plated/coated with an electrically conductive protective coating layer.

FIG. 11 is a cross-section view of a different embodiment of the wafer processing apparatus shown in FIG. 9, but with the application of a corrosion resistant filler.

FIG. 12 is a cross-section view of a different embodiment of the wafer processing apparatus shown in FIG. 3, where additionally recesses are drilled into the ceramic core substrate for using with a machined conductive insert.

FIG. 13 is a cross-section view of a different embodiment of the wafer processing apparatus shown in FIG. 12, except for that the threaded insert is replaced with a rod and additional nut.

FIG. 14 is a cross-section view of a different embodiment of the wafer processing apparatus shown in FIG. 3, where additionally recesses are drilled into the ceramic core substrate for use with machined conductive threaded inserts.

FIG. 15 is a cross-section view of a different embodiment of the wafer processing apparatus shown in FIG. 14, wherein the over-coating layer is only applied on the surfaces that are not going to be in contact with the wafer.

FIG. 16 is a cross-section view of a different embodiment of the wafer processing apparatus shown in FIG. 14, wherein recesses and/or raised areas and/or mesas are incorporated onto the substrate surface.

FIG. 17 is a cross-section view of a different embodiment of the wafer processing apparatus shown in FIGS. 15 and 16, combining the features of both.

FIG. 18 is a cross-section view of another embodiment of the wafer handling apparatus of the invention, where an electrically conductive substrate is employed.

FIG. 19 is a cross-section view of a different embodiment of the wafer processing apparatus shown in FIG. 18, wherein coated through holes are employed.

FIG. 20 illustrates the cross-section view of yet another embodiment the wafer handling apparatus of the invention, wherein the electrode is partly exposed and a corrosion resistant washer is applied.

FIG. 21 is a cross-section view of a different embodiment of the wafer processing apparatus shown in FIG. 20, wherein a bolt is used with a coated through-hole.

### DETAILED DESCRIPTION OF THE INVENTION

As used herein, approximating language may be applied to modify any quantitative representation that may vary without resulting in a change in the basic function to which it is related. Accordingly, a value modified by a term or terms, such as “about” and “substantially,” may not to be limited to the precise value specified, in some cases.

As used herein, the term “substrate” and “wafer” may be used interchangeably; referring to the semiconductor wafer substrate being supported/heated by the apparatus of the invention. Also as used herein, the “treating apparatus” may be used interchangeably with “handling apparatus,” “heater,” “heating apparatus,” or “processing apparatus,” referring to an apparatus containing at least one heating element to heat the wafer supported thereon.

As used herein, the term “circuit” may be used interchangeably with “electrode,” and the term “resistance heating element” may be used interchangeably with “resistor,” or “heating resistor.” The term “circuit” may be used in either the single or plural form, denoting that at least one unit is present.

As used herein, a component (e.g., a layer or a part) having a closely matched coefficient of thermal expansion (CTE) means that the CTE of the component is between 0.75 to 1.25 of the CTE of the adjacent component (another layer, a substrate, or another part).

As used herein, the term “functional members” of a wafer processing apparatus include but are not limited to, holes, tabs on the edge of the heater, contacts to the electrode, or inserts in the substrate to meet other functional requirements of the wafer processing apparatus.

As used herein, the term “etch-resistant” may be used interchangeably with “corrosion resistant,” referring to a material that is etch-resistant, or having a low-etch rate in a harsh environment, i.e., an environment comprising halogens or when exposed to plasma etching, reactive ion etching, plasma cleaning, or gas cleaning at an operating temperature of at least 400° C. in one embodiment, 500° C. in a second embodiment, and 800° C. in a second embodiment.

In one embodiment, the etch-resistant rate is less than 1000 Angstroms per minute (Å/min) in a harsh environment operated in a temperature range of 25-600° C. In a second embodiment, the etch rate is less than 500 Angstroms per minute (Å/min) for a temperature range of 25-600° C. In a third embodiment, the rate is less than 100 Angstroms per minute (Å/min) for a temperature range of 25-600° C. In a fourth embodiment, the rate is less than 1000 Angstroms per minute (Å/min) in a temperature range of 200-600° C. In a fifth embodiment, the rate is less than 500 Angstroms per minute (Å/min) in a temperature range of 200-600° C.

In one aspect of the invention, the electrode comprises at least one of molybdenum, nickel, cobalt, iron, tungsten, ruthenium, and alloys thereof, and the protective coating layer comprises at least one of aluminum nitride, aluminum oxide, aluminum oxynitride or combinations thereof, having CTE ranging from 0.75 to 1.25 of the CTE of the base substrate.

Embodiments of the wafer processing apparatus of the invention are illustrated as follows, by way of a description of the materials being employed, the manufacturing process thereof and also with references to the figures.

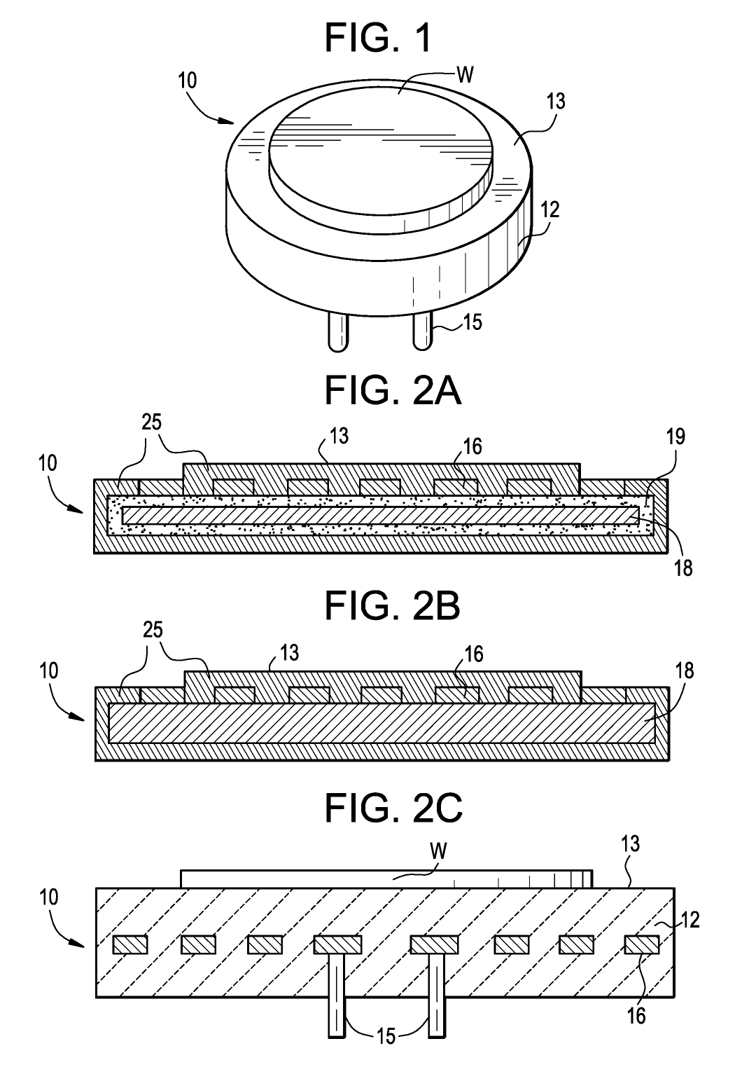

General Embodiments of the Wafer Processing Apparatus: In one embodiment as illustrated in FIG. 1, a wafer processing apparatus refers to a disk-shaped dense ceramic substrate 12, whose top surface 13 serves as a supporting surface for a wafer W, having a heating resistor 16 buried therein (not shown). Electric terminals 15 for supplying electricity to the heating resistor can be attached at the center of the bottom surface of the ceramic substrate 12, or in one embodiment, at the sides of the ceramic substrate. The wafer W placed on the top surface 14 of the heater is uniformly heated by applying a voltage to the supply terminals 15, thereby causing the heating resistor to generate heat.

With respect to the base substrate of the wafer processing apparatus of the invention, in one embodiment as illustrated in FIG. 2A, the base substrate comprises a disk or substrate 18 containing an electrically conductive material, having an overcoat layer 19 that is electrically insulating, and optionally a tie-layer (not shown) to help enhance the adhesion between the electrically insulating coating layer 19 and the base substrate 18. The electrically conductive material of disk 18 is selected from the group of graphite; refractory metals such as W and Mo, transition metals, rare earth metals and alloys; oxides and carbides of hafniium, zirconium, and cerium, and mixtures thereof.

With respect to the overcoat layer 19 of the electrically conducting disk 18, the layer 19 comprises at least one of an oxide, nitride, carbide, carbonitride or oxynitride of elements selected from a group consisting of B, Al, Si, Ga, Y, refractory hard metals, transition metals; oxide, oxynitride of aluminum; and combinations thereof. With respect to the optional tie-layer, the layer comprises at least one of: a nitride, carbide, carbonitride, boride, oxide, oxynitride of elements selected from Al, Si, refractory metals including Ta, W, Mo, transition metals including titanium, chromium, iron; and mixtures thereof. In one embodiment, the tie-layer comprises at least one of a TiC, TaC, SiC, MoC, and mixtures thereof.

In one embodiment as illustrated in FIG. 2B, wherein the base substrate 18 comprises an electrically insulating material (e.g., a sintered substrate), the material is selected from the group of oxides, nitrides, carbides, carbonitrides or oxynitrides of elements selected from a group consisting of B, Al, Si, Ga, Y, high thermal stability zirconium phosphates, having the NZP structure of NaZr₂(PO₄)₃; refractory hard metals; transition metals; oxide, oxynitride of aluminum; and combinations thereof, having high wear resistance and high heat resistance properties. In one embodiment, the base substrate 18 comprises AlN, which has a high thermal conductivity of >50 W/mk (or sometimes >100 W/mk), high resistance against corrosion by corrosive gases such as fluorine and chlorine gases, and high resistance against plasma, in particular. In one embodiment, the base substrate comprises a high-purity aluminum nitride of >99.7% purity and a sintering agent selected from Y₂O₃, Er₂O₃, and combinations thereof

In one embodiment as illustrated in FIG. 2C, heating element or electrode 16 having an optimized circuit design is “buried” in the ceramic substrate 12. The heating element 16 comprises a material selected from metals having a high melting point, e.g., tungsten, molybdenum, rhenium and platinum or alloys thereof, carbides and nitrides of metals belonging to Groups IVa, Va and VIa of the Periodic Table; carbides or oxides of hafnium, zirconium, and cerium, and combinations thereof. In one embodiment, the heating element 16 comprises a material having a CTE that closely matches the CTE of the substrate (or its coating layer).

In another embodiment as illustrated in FIGS. 2A-2B, the heating element comprises a film electrode 16 having a thickness ranging from 1 to 1000 μm. In a second embodiment, the film electrode 16 has a thickness of 5 to 500 μm. The film electrode 16 can be formed on the electrically insulating base substrate 18 (of FIG. 2B) or the coating layer 19 (of FIG. 2A) by processes known in the art including screen-printing, spin coating, plasma spray, spray pyrolysis, reactive spray deposition, sol-gel, combustion torch, electric arc, ion plating, ion implantation, ion plasma deposition, sputtering deposition, laser ablation, evaporation, electroplating, and laser surface alloying. In one embodiment, the film electrode 16 comprises a metal having a high melting point, e.g., tungsten, molybdenum, rhenium and platinum or alloys thereof In a second embodiment, the film electrode 16 comprises a noble metal or a noble metal alloy. In a third embodiment, the film electrode 16 comprises at least one of carbides or oxides of hafnium, zirconium, cerium, and mixtures thereof.

In one embodiment, the sheet resistance of the electrode is controlled within a range of 0.001 to 0.10 Ω/sq to meet the electrical resistance requirement for the electrode, while maintaining the optimal path width and space between the paths of the electrode pattern. In a second embodiment, the sheet resistance is controlled within a range of 0.005 to 0.05 Ω/sq. The sheet resistance is defined as the ratio of electrical resistivity to film thickness.

In the wafer processing apparatus of the invention, one or more electrodes can be employed. Depending on the application, the electrode may function as a resistive heating element, a plasma-generating electrode, an electrostatic chuck electrode, or an electron-beam electrode.

In one embodiment of the invention as illustrated in FIGS. 2A and 2B, the wafer processing apparatus 10 is further coated with a protective coating film 25 which is etch-resistant.

In one embodiment, the protective coating layer 25 comprises at least a nitride, carbide, carbonitride or oxynitride of elements selected from a group consisting of B, Al, Si, Ga, Y, refractory hard metals, transition metals, and combinations thereof, having a CTE ranging from 2.0×10⁻⁶/K to 10×10⁻⁶/K in a temperature range of 25 to 1000° C.

In one embodiment, the protective coating layer 25 comprises a high thermal stability zirconium phosphates, having the NZP structure. The term NZP refers to NaZr₂ (PO₄)₃, as well as to related isostructural phosphates and silicophosphates having a similar crystal structure. These materials in one embodiment are prepared by heating a mixture of alkali metal phosphates or carbonates, ammonium dihydrogen phosphate (or diammonium phosphate) and tetravalent metal oxides.

In one embodiment, the NZP-type coating layer 25 has a general formula: (L,M1,M2,Zn,Ag,Ga,In,Ln,Y,Sc)₁(Zr,V,Ta,Nb,Hf,Ti,Al,Cr,Ln)ₘ(P,Si,VAl)ₙ(O,C,N)₁₂ wherein L=alkali, M1=alkaline earth, M2=transition metal, Ln=rare earth and the values of l, m, n are so chosen that a charge balance is maintained. In one embodiment, the NZP-type protective coating layer 25 includes at least one stabilizer selected from the group of alkaline earth oxides, rare earth oxides, and mixtures thereof. Examples include yttria (Y₂O₃) and calcia (CaO).

In a third embodiment, the protective coating layer 25 contains a glass-ceramic composition containing at least one element selected from the group consisting of elements of the group 2a, group 3a and group 4a of the periodic table of element. The group 2a as referred to herein means an alkaline earth metal element including Be, Mg, Ca, Sr and Ba. The group 3a as referred to herein means Sc, Y or a lanthanoid element. The group 4a as referred to herein means Ti, Zr or Hf Examples of suitable glass-ceramic compositions for use as the coating layer 25 include but are not limited to lanthanum aluminosilicate (LAS), magnesium aluminosilicate (MAS), calcium aluminosilicate (CAS), and yttrium aluminosilicate (YAS).

In one example, the protective coating layer 25 contains a mixture of SiO₂ and a plasma-resistant material comprising an oxide of Y, Sc, La, Ce, Gd, Eu, Dy, or the like, or a fluoride of one of these metals, or yttrium-aluminum-garnet (YAG). Combinations of the oxides of such metals, and/or combinations of the metal oxides with aluminum oxide, may be used. In a third embodiment, the protective coating layer 25 comprises from 1 to 30 atomic % of the element of the group 2a, group 3a or group 4a and from 20 to 99 atomic % of the Si element in terms of an atomic ratio of metal atoms exclusive of oxygen. In one example, the layer 25 includes aluminosilicate glasses comprising from 20 to 98 atomic % of the Si element, from 1 to 30 atomic % of the Y, La or Ce element, and from 1 to 50 atomic % of the Al element, and zirconia silicate glasses comprising from 20 to 98 atomic % of the Si element, from 1 to 30 atomic % of the Y, La or Ce element, and from 1 to 50 atomic % of the Zr element.

In another embodiment, the protective coating layer 25 is based on Y₂O₃—Al₂O₃—SiO₂(YAS), with the yttria content varying from 25 to 55 wt. % for a melting point of less than 1600° C. and a glass transition temperature (Tg) in a narrow range of 884 to 895° C., with optional dopants added to adjust the CTE to match that of the adjacent substrate. Examples of dopants include BaO, La₂O₃, or NiO to increase the CTE of the glass, and ZrO₂ to decrease the CTE of the glass. In yet another embodiment, the protective coating layer 25 is based on BaO—Al₂O₃—B₂O₃—SiO₂ glasses, wherein La₂O₃, ZrO₂, or NiO is optionally added to adjust the CTE of the glass to appropriate match the CTE of the substrate. In one example, the coating layer 25 comprises 30-40 mol % BaO, 5-15 mole % Al₂O₃; 10-25 mole % B₂O₃, 25-40 mole % SiO2; 0-10 mole % of La₂O₃; 0-10 mole % ZrO₂; 0-10 mole % NiO with a molar ratio B₂O3/SiO₂ ranging from 0.25 to 0.75.

The protective coating layer 25 can accommodate small concentrations of other non-metallic elements such as nitrogen, oxygen and/or hydrogen without any deleterious effects on corrosion resistance or etch resistance. In one embodiment, the coating layer contains up to about 20 atomic percent (atom %) of hydrogen and/or oxygen. In another embodiment, the protective coating 25 comprises hydrogen and/or oxygen up to about 10 atom %.

The protective coatings layer 25 may be deposited on substrates by processes known in the art, including thermal/flame spray, plasma discharge spray, expanding thermal plasma (ETP), ion plating, chemical vapor deposition (CVD), plasma enhanced chemical vapor deposition (PECVD), metal organic chemical vapor deposition (MOCVD) (also called Organometallic Chemical Vapor Deposition (OMCVD)), metal organic vapor phase epitaxy (MOVPE), physical vapor deposition processes such as sputtering, reactive electron beam (e-beam) deposition, ion plasma deposition, and plasma spray. Exemplary processes are thermal spray, ETP, CVD, and ion plating.

The thickness of the protective coating layer 25 varies depending upon the application and the process used, e.g., CVD, ion plating, ETP, etc, varying from 1 μm to a few hundred μm, depending on the application. Longer life cycles are generally expected when thicker protective layers are used.

Corrosion Resistant Connectors and Configurations: In a typical wafer processing environment with the use of corrosive gases, atomic entry of the fluorine based gases can rapidly attack components of the wafer processing apparatus through the contact areas or functional members with mechanical components such as electrical connections, inserts including but not limited to gas feed-through channels, recessed areas, raised areas, MESA, through-holes such as lift-pin holes, threaded bolt holes, blind holes, and the like. Example of functional members include but are not limited electrical leads, tabs, inserts, and through-holes, etc, which penetrates through the contact areas, thus creating a gap for corrosive gases to attack the base components such as the substrate.

In one embodiment of the invention, the leads to the electrode, mechanical components and fasteners for attaching function members are coated with an electrically conductive etch resistant material having sufficient ductility property to conform the thermal expansion of the base material. In another embodiment, the electrode itself is coated with the electrically conductive etch-resistant material. Examples of suitable etch-resistant materials include but are not limited to nickel, chromium, superalloys, or other conductive materials that have a ductility of >5% when applied as a coating layer.

In one embodiment of the invention, customized connectors are used providing etch resistant protection to the connection. In a second embodiment, etch resistant electrically conductive materials are used to protect exposed electrical connectors from the corrosive environment.

In yet another embodiment, etch resistant compositions are used as fillers, adhesives, glues, or sealants to further provide protection to the contact connections from atomic entry of corrosive gases.

Embodiments of the corrosion resistant connections of the invention are further illustrated as follows with references to the figures.

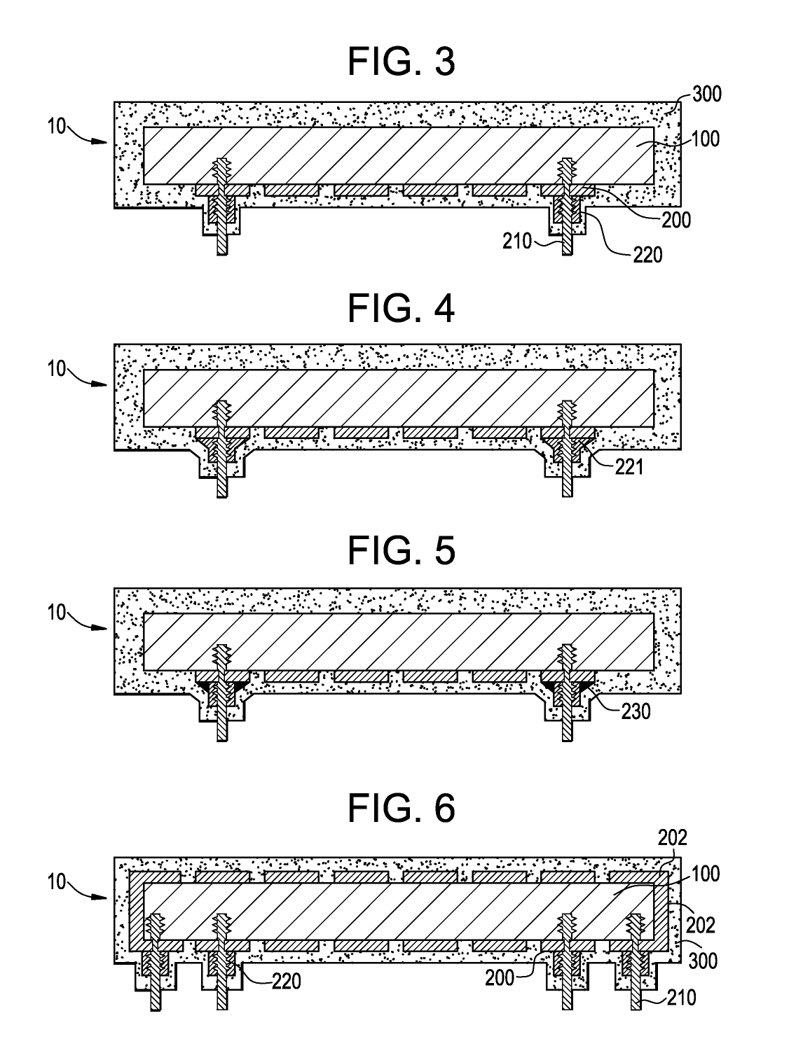

FIG. 3 is a cross-section diagram of one embodiment of the wafer handling apparatus 10 of the invention with a patterned electrode 200 on a surface of a base substrate 100, over-coated with a corrosion resistant coating layer 300. The patterned electrode 200 can function as a heater electrode and/or a chucking electrode, depending on the application.

A conector nut 220 is used to fasten a threaded connector rod 210 into place. In one embodiment, the threaded connector rod 210 and connector nut 220 are made from the same refractory metal material with a CTE that closely matches the CTE of the substrate 100 and the over-coating layer 300. An example is molybdenum with a CTE that closely matches the CTE of the AlNlayer. In a second embodiment, they are of different materials with closely matched CTEs. In one embodiment, the rod 210 and/or nut 220 are additionally plated with Nickel or other conductive etch resistant materials (not shown). As illustrated, the rod 210 is threaded into a threaded hole in the substrate 100. In one embodiment (not shown), the rod 210 is press-fit into a blind hole in the substrate, or glued into a hole in the substrate 100.

As it is sometimes difficult to provide adequate coating in sharp corners or crevices in the deposition process, i.e., called “partial shadowing,” which could possibly result in a thinner over-coating limiting the life of the wafer handling apparatus, FIG. 4 is a cross-section diagram of a different embodiment of FIG. 3 to address the partial shadowing. In this embodiment, the connector nut 221 has tapered features to facilitate the over-coating process to sufficiently coat in the transition region from nut 221 to substrate 100. In yet another configuration (not shown), the nut 221 has rounded corners which reduce the stress in the over-coating and the probability of delamination in operations.

In yet another embodiment of the wafer handling apparatus 10 as illustrated in FIG. 5, the connector nut 221 is further provided with a sealer, i.e., a bead of corrosion resistant, high temperature compatible filler 230 in the transition region from nut to substrate. In one embodiment, the filler 230 functions as the tapered nut in FIG. 4 to minimize partial shadowing of the deposition process. In another embodiment, the filler 230 provides a second line of defense to corrosive species in the event that the over-coating layer 300 does not provide adequate protection and gets consumed prematurely.

FIG. 6 is a cross-section diagram of another embodiment of the assembly 10 illustrated in FIG. 3, except with the addition of an additional electrode 202. As illustrated, electrode 200 could be a heater electrode and the other electrode 202 could be a chucking electrode. Alternatively the two electrodes could be independently controlled heater electrodes. In another embodiment, the electrodes could be independently controlled chucking electrodes.

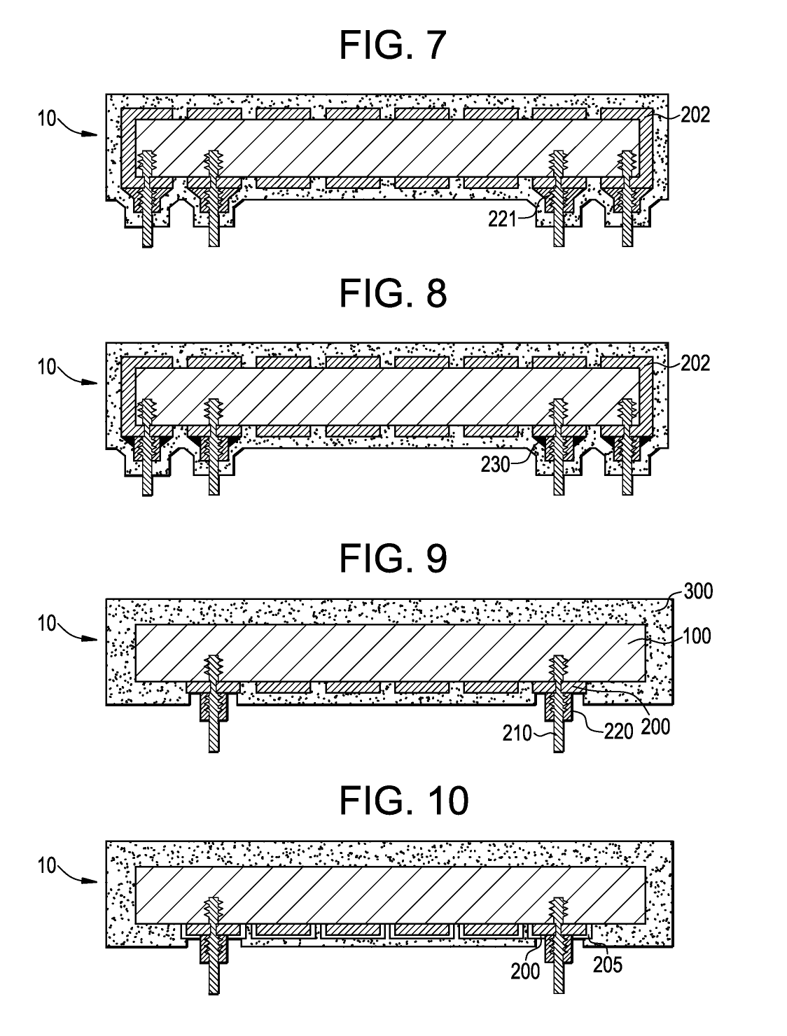

FIG. 7 is a cross-section diagram of another embodiment of the assembly 10 illustrated in FIG. 4 with a tapered connector nut 221, with the addition of one additional electrode 202, which can function as a heater electrode or a chucking electrode.

FIG. 8 is a cross-section diagram of a heater embodiment of the assembly 10 illustrated in FIG. 5 with the addition of a second electrode 202 to the substrate. As shown, sealer/filler 230 provides a transition region from nut to substrate for all electrical connections.

FIG. 9 is a cross-section diagram of another embodiment of the wafer handling apparatus 10. In this embodiment, the corrosion resistant connector rod 210 and nut 220 are applied after the overcoat 300 is applied and partially removed at the contact areas. Also in this embodiment, the (partly exposed) electrode 200, the connector rod 210, nut 220, other components such as washers, springs, etc (not shown) are electrically conductive and corrosion resistant. In one embodiment, these components comprise a corrosion resistant electrically conductive material selected from the group of Nickel, Cobalt, iron, oxides and carbides of hafnium, zirconium, and cerium, and mixtures thereof, having a CTE that closely matches the CTE of the substrate 100. Examples include but are not limited to commercially available superalloys under the trade names of Invar and Kovar. This configuration allows lower melting temperature corrosion resistant connector materials, e.g., aluminum and alloys, hafnium and zirconium carbides and nitrides, etc., to be used as the connector component that do not need to be able to survive the over-coating process. Over-coating processes to apply the overcoat layer 300 can sometimes be a high temperature process such as thermal spray, high temperature CVD or other deposition processes.

FIG. 10 is a cross-section diagram of a variation of the embodiment of FIG. 9. In this embodiment, the electrode 200 is plated/coated with an electrically conductive protective coating 205. The protective coating 205 in one embodiment comprises an etch-resistant and electrically conductive material selected from the group of nickel, cobalt, iron; oxides and carbides of hafnium, zirconium, and cerium, and mixtures thereof, having a CTE that closely matches the CTE of the electrode 200. The coating 205 can be applied onto the electrode 200 using processes known in the art, including but not limited to electroplating, electroless plating, painting, spraying, evaporation, sputtering, CVD, etc.

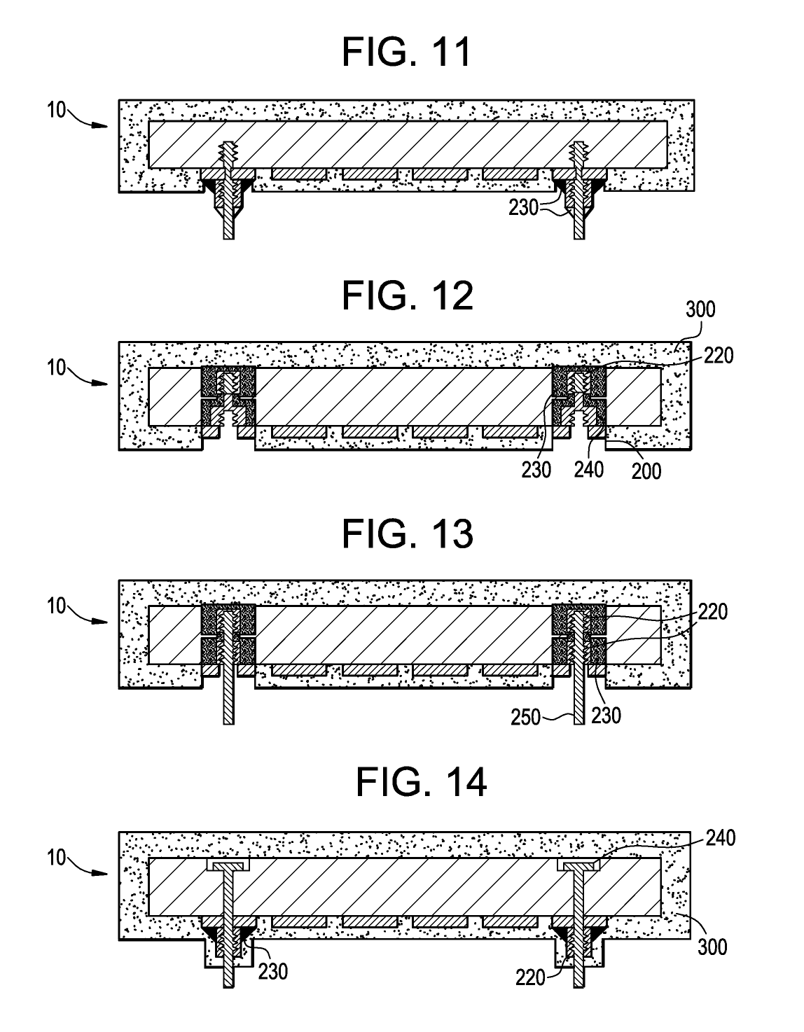

FIG. 11 is a cross-section diagram of another embodiment of the invention, wherein the electrode 200 is provided with a corrosion resistant filler 230. The use of the corrosion resistant filler/sealant 230 obviates the need for a corrosion resistant material for the electrode 200 or a protective coating layer 205 on the electrode (as illustrated in FIG. 10). In one embodiment, the electrode 200 comprises molybdenum, a material with a CTE that closely matches the CTE of AlNas the substrate, but does not have the requisite corrosion resistant properties for certain wafer processing environments with corrosive fluorine gases.

In FIG. 12 of another embodiment, recesses are drilled into the ceramic core substrate of the apparatus 10, and a machined conductive threaded insert 240 is installed in the recesses and bolted in place with a recessed nut 220. The space around the rod and nuts is filled with a corrosion resistant filler 230. In this embodiment, the threaded insert 240, nut 220 and filler 230 are applied and assembled in place first, prior to the application of the electrode 200 and subsequent over-coating layer 300. Connector rod 210 (not shown) can be screwed into the machined threaded insert after over-coating. The use of threaded inserts and fillers in this embodiment is particularly advantageous in applications wherein it is challenging to machine threaded holes in ceramic substrates. Inserts can also be used in applications wherein it may be difficult to apply or select an adhesive with matching CTE for use in a press fitting assembly.

FIG. 13 is a variation of the embodiment of FIG. 12, wherein a rod 250 assembly is used instead of the threaded insert, and an additional nut 220 is provided to further strengthen and provide protection to the connection.

FIG. 14 is a sectional-view of yet another embodiment with the use of inserts. As illustrated, machined conductive inserts 240 are installed in the recesses drilled in the ceramic substrate. The inserts are additionally plated with nickel or other conductive etch resistant material (not shown) The inserts are bolted in place with nuts 220. The inserts are of sufficient length so that they stick out of the surface of the substrate (opposite the side where the wafer would be contacting the wafer processing apparatus). The free space around the nuts 220 are filled with corrosion resistant filler 230. In this embodiment, the inserts 240, nut 220 and filler 230 are applied into final assembly after the application of the electrode 200, but prior to the application of the over-coating layer 300.

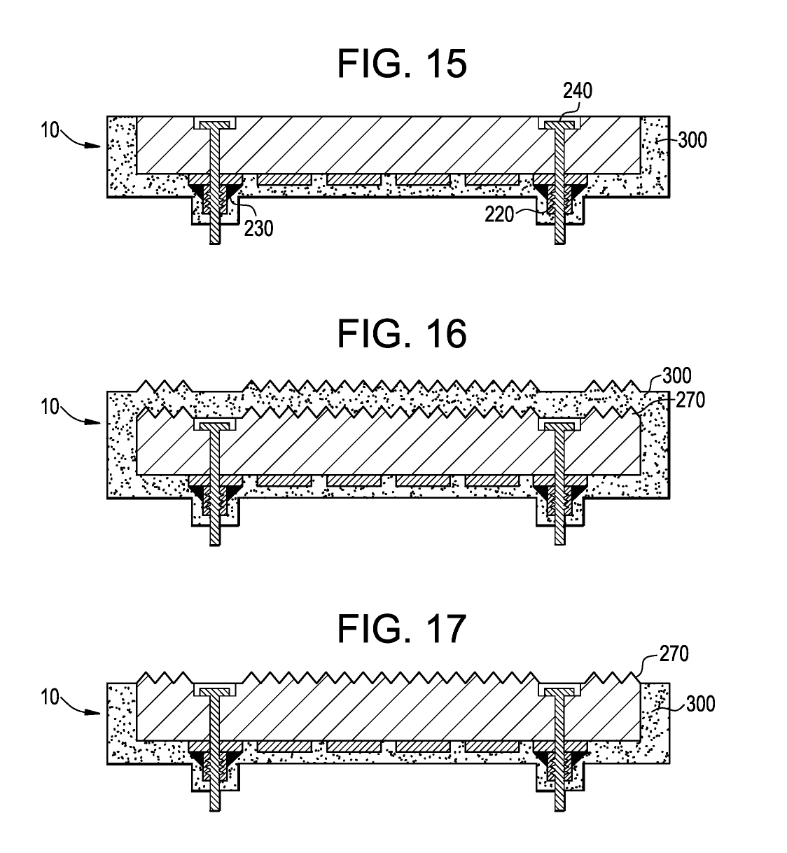

FIG. 15 is a slight variation of the wafer processing apparatus of FIG. 14. In this embodiment, the over-coating layer 300 is only applied on the surfaces that are not to be in contact with the wafer. For some applications, occasionally an over-coating layer 300 could comprise non-idealities, i.e., defects and undesirable elements such as nodules due to dust and gas phase nucleation, or uneven coating/non-uniform coating thickness. The non-idealities in the surface would prevent the wafer from making optimum thermal contact and/or placing the wafer out of focus. By avoiding deposition on the wafer contacting surface as in the embodiment of this FIG. 15, the imperfections can be mitigated.

FIG. 16 shows a variation of the embodiment in FIG. 14, further comprising features like recesses and/or raised areas and/or mesas 270 in the substrate. In one embodiment, the raised areas are for the entire substrate surface. In another embodiment, the raised surfaces 270 are for at least the surface that is contacting the wafer. The over-coating layer 300 is applied to follow the general contours of these features 270. In some embodiments, the raised surface areas also mitigate the imperfections/risks due to non-idealities due to the reduced overall contact area with the wafer.

FIG. 17 is a cross-section diagram showing an embodiment that combines the features of the apparatus in FIGS. 15 and 16 with uncoated raised surfaces 270, thus minimizing the poor wafer contact problems due to non-idealities like nodules and uneven or non-uniform over-coating thickness.

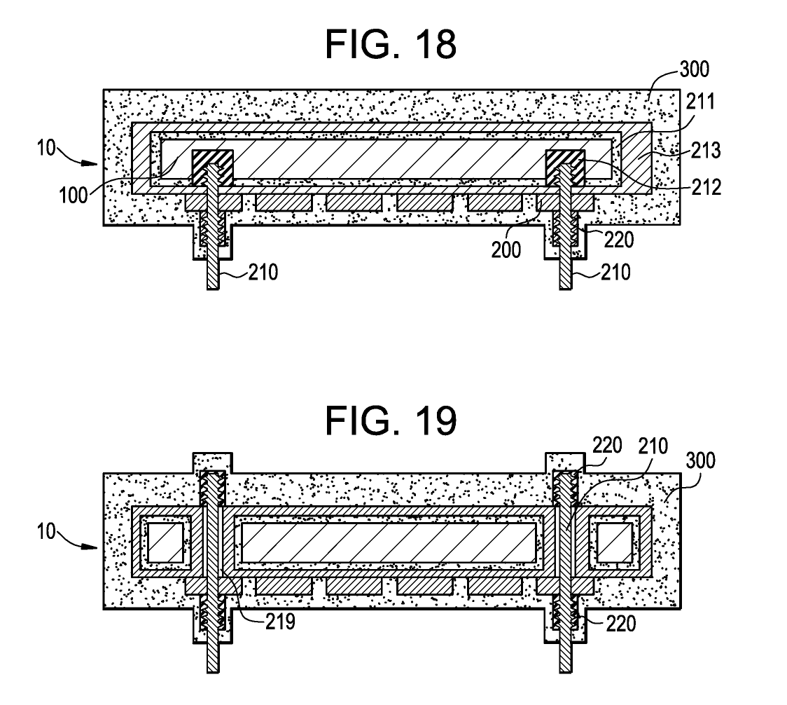

FIG. 18 illustrates another embodiment of the wafer handling apparatus 10. In this embodiment, the substrate 100 is not a ceramic but an electrically conductive material, e.g., graphite or a high melting metal such as Molybdenum. As illustrated, the substrate 100 is further coated with (an optional) tie-layer or adhesion promoting layer 211, e.g., TaC. An insulating insert 212 is inserted into the substrate 210 by means known in the art, e.g., press-fit, glued, or threaded. The substrate is subsequently coated with an insulating basecoat layer 213. In the next step, electrode 200 is installed, followed by the insertion of rod 210 and nut 220, and lastly, followed by application of the over-coating layer 300. The insulating basecoat layer 213 can be the same or different material from the over-coating layer 300, with both layers being applied by coating processes known in the art including but not limited to CVD, thermal CVD, ETP, ion plating, etc.

FIG. 19 illustrates a variation of the embodiment in FIG. 18. In this embodiment, ceramic inserts are replaced by the use of coated through-holes 219, through which an electrode rod 210 is inserted and nuts 220 can be attached on either side of the rod 210, prior to the application of over-coating layer 300. In one embodiment (not shown), the nuts 220 are tapered/rounded. In another embodiment (not shown), filler 230 is used to further seal/provide protection to the connection.

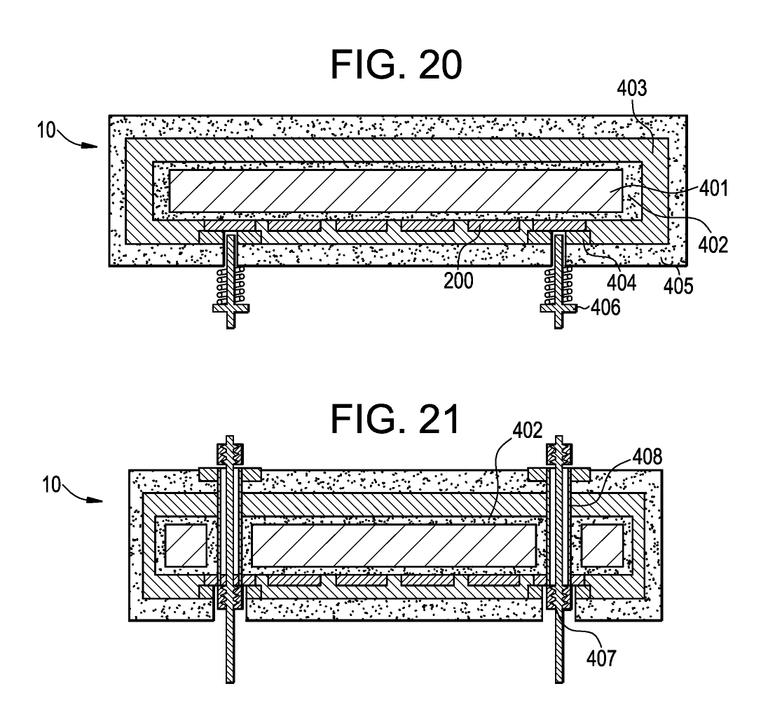

FIG. 20 is a cross-section view of yet another embodiment of the wafer handling apparatus 10. In this embodiment, substrate 401 comprises an electrically conductive material such as graphite, over-coated with an electrically insulating layer 402 comprising a material such as pyrolytic boron nitride. An electrode 200, e.g. of pyrolytic graphite, is applied on the coating layer 402. In one embodiment as illustrated, the electrode 200 is coated with at least one additional insulating coating layer 403. In the next step, the electrode 200 is partly exposed so that a corrosion resistant washer 404, such as a sintered aluminum nitride washer, is applied. The entire assembly is then over-coated with an etch resistant pyrolytic graphite coating layer 405. Finally, electrically conductive corrosion resistant press contacts 406, e.g. spring-loaded contacts comprising materials such as hafnium nitride, cobalt, nickel, Kovar superalloy, etc, are put in place.

FIG. 21 is a variation of the embodiment of FIG. 20, wherein a bolt 407 is used instead of the corrosion resistant press contacts. In this embodiment, bolt 407 is inserted through through-hole lined with a corrosion resistant insulating liner 408. In one embodiment, the lined through-hole is in the form of sintered ceramic tubing.

It should be noted that the corrosion resistant configurations of the invention are not limited to the illustrated embodiments, features of the embodiments may be combined and or modified, allowing variations from the embodiments without departing from the concept of a wafer processing with corrosion resistant connections.

Corrosion Resistant Filler/Adhesive/Protective Sealant: As illustrated in the Figures of various embodiments of the invention with corrosion resistant connections, a corrosion resistant filler 230 is used in a number of embodiments.

As used herein, the term “filler” may be used interchangeably with “sealant,” “glue,” “adhesive,” or “protective sealant,” referring to a material that can further protect components in wafer processing apparatuses such as electrodes, connectors, rods, fasteners such as nuts, rivets, etc. from microscopic attacks in the wafer processing chamber. The filler can comprise any ceramic, glass, or glass-ceramic material that exhibits resistance to elevated temperature and is thermally compatible with the substrate and other components, e.g., the graphite heater element, metal fasteners, etc. The filler is also chemically compatible with the semiconductor processing environment.

A filler is regarded herein as thermally compatible if the coefficient of thermal expansion (CTE) of the filler matrix closely matches the CTE of the adjacent substrate, thus the differential thermal expansion of materials during thermal cycling does not result in delamination or peeling of the filler. In one embodiment, the filler comprises a material having a CTE having a value in-between that of the ceramic substrate and the metallic interconnect/fastener. Borosilicate glass, aluminosilicate glass and high silica glass as well as mixtures of glass are examples of suitable fillers.

A filler regarded herein as chemically compatible for use in a semiconductor processing environment means a filler that is low in the reactivity with a corrosive gas or its plasma; even if a reaction with fluorine in the corrosive gas occurs, the formed substances are a high-boiling compound; and it is effective for suppressing corrosion caused by the plasma or corrosive gas.

In one embodiment, the filler composition contains at least one element selected from the group consisting of elements of the group 2a, group 3a and group 4a of the periodic table of element. The group 2a as referred to herein means an alkaline earth metal element including Be, Mg, Ca, Sr and Ba. The group 3a as referred to herein means Sc, Y or a lanthanoid element. The group 4a as referred to herein means Ti, Zr or Hf.

Examples of suitable compositions for use as fillers include but are not limited to lanthanum aluminosilicate (LAS), magnesium aluminosilicate (MAS), calcium aluminosilicate (CAS), and yttrium aluminosilicate (YAS). The choice of a particular matrix material is based on the anticipated demands of the intended application. In one embodiment, the matrix material is selected to match a heater application with AlNcoating layer with a theoretical average CTE of 4.9×10⁻⁶/K, a graphite heater element having a theoretical CTE of 5.3×10⁻⁶/K In another embodiment, a filler is selected for a CTE value in-between the CTE of the AlNcoating layer of 4.9×10⁻⁶/K and the CTE of the refractory metal fasteners, comprising a material such as tungsten W, molybdenum Mo, tantalum Ta, or alloys such as copper tungsten (CuW), copper molybdenum (CuMo with a CTE of 6.9 ppm/C for 85/15 MoCu), molybdenum manganese (MoMn) etc.

In one embodiment, the filler is a composition based on BaO—Al₂O₃—B₂O₃—SiO₂ glasses, wherein La₂O₃, ZrO₂, and NiO is optionally added to adjust the CTE of the glass to appropriate match the CTE of the substrate. In one embodiment, the composition comprises 30-40 mol % BaO, 5-15 mole % Al₂O₃; 10-25 mole % B₂O₃, 25-40 mole SiO2; 0-10 mole % of La₂O₃; 0-10 mole % ZrO₂; 0-10 mole % NiO with a molar ratio B₂O3/SiO₂ ranging from 0.25 to 0.75. In another embodiment, La₂O₃, ZrO₂, or NiO is added in an amount sufficient for the filler to have a CTE matching that of AlN as a coating layer and graphite as a base layer, with the addition of La₂O₃ and NiO increasing the CTE of the glasses and the addition of ZrO₂ decreases the CTE of the glasses.

In another embodiment, the filler is a composition based barium lanthanum silicate (BLS) glass, with general compositions ranging from 30-35 mole % BaO, 10-15 mole % La₂O₃, and 50-60 mole % SiO₂, for glasses having CTE of 10-12 ppm and softening temperature in the range of 750° C. to 850° C.

In yet another embodiment, the filler is a composition based on Y₂O₃—Al₂O₃—SiO₂ (YAS) glasses, with the yttria content varying from 25 to 55 wt. % for a melting point of less than 1600° C. and a glass transition temperature (Tg) in a narrow range of 884 to 895° C., and wherein the CTE generally increases with increasing Y₂O₃ and decrease with increasing SiO₂. In one embodiment, the YAS filler composition comprises 25-55 wt. % Y₂O₃, 13 to 35 wt. % Al₂O₃, and 25 to 55 wt. % SiO₂ for a CTE ranging from 31 to 70 10⁻⁷/K. In a second embodiment, the YAS composition comprises 17 Y₂O₃-19 Al₂O₃-64 SiO₂ all in mol. % for excellent chemically durable properties.

In one embodiment, dopants are added to YAS glass composition in an amount sufficient to optimize the CTE to match that of the adjacent substrate. Examples of dopants include BaO, La₂O₃, ZrO₂, or NiO, with most components to increase the CTE of the glass, with the exception of ZrO₂ which decreases the CTE of the glass.

In one embodiment, the filler composition comprises from 1 to 30 atomic % of the element of the group 2a, group 3a or group 4a and from 20 to 99 atomic % of the Si element in terms of an atomic ratio of metal atoms exclusive of oxygen. In one embodiment of an aluminosilicate glass, the composition comprises from 20 to 98 atomic % of the Si element, from 1 to 30 atomic % of the Y, La or Ce element, and from 1 to 50 atomic % of the Al element. In yet another embodiment, the aluminosilicate glass has a composition such that the atomic ratio of the respective metal elements (Si:Al:group 3a) falls within the range connecting respective points of (70:20:10), (50:20:30), (30:40:30), (30:50:20), (45:50:5) and (70:25:5). In one embodiment of a zirconia silicate glass filler, the composition comprises from 20 to 98 atomic % of the Si element, from 1 to 30 atomic % of the Y, La or Ce element, and from 1 to 50 atomic % of the Zr element. In one example, the zirconia silicate glass has a composition such that the atomic ratio of the respective metal elements (Si:Zr:group 3a) falls within the range connecting respective points of (70:25:5), (70:10:20), (50:20:30), (30:40:30), (30:50:20) and (45:50:5). In another embodiment of a zirconia silicate glass filler, the atomic ratio of the respective metal elements (Si:Zr:group 3a) falls within the range connecting respective points of (70:25:5), (70:10:20), (50:22:28), (30:42:28), (30:50:20) and (45:50:5). In the case of a group 2a-containing zirconia silicate glass, the zirconia silicate glass has a composition such that the atomic ratio of the respective metal elements (Si:Zr:group 2a) falls within the range connecting respective points of (70:25:5), (45:25:30), (30:40:30), (30:50:20) and (50:45:5).

In one embodiment, the filler composition is a mixture of SiO₂ and a plasma-resistant material comprising an oxide of Y, Sc, La, Ce, Gd, Eu, Dy, or the like, or a fluoride of one of these metals, or yttrium-aluminum-garnet (YAG). Combinations of the oxides of such metals, and/or combinations of the metal oxides with aluminum oxide, may be used. For example, Y₂O₃ can be used in combination with a minority percentage of Al₂O₃ (typically, less than about 20% by volume) to match the CTE of the glass filler composition with the underlying substrate of the heater.

Method for Forming & Applications of the Filler Composition: In one embodiment, the filler composition is in the form of a paste or paint, to be applied as a “filler” around the contact elements of the wafer processing device of the invention. In one embodiment, the composition is applied as a paste, spreading around the contact elements or fasteners forming a “bead.” In a second embodiment, the composition is applied as a paint, being sprayed or brushed onto the contact elements or fasteners forming a protective coating layer of at least 0.1 mil, protecting the connections from chlorine or fluorine species in a semiconductor processing environment. In a third embodiment, a protective coating layer of at least 0.5 mil is applied.

In yet another embodiment, the filler composition is applied broadly onto the heater assembly using a process known in the art for applying glass-ceramics, including thermal/flame spray, plasma discharge spray, sputtering, and chemical vapor deposition, for a coating/sealant layer of at least 0.5 mil to seal openings, cracks, etc. between the contact elements and the adjacent parts, as well as providing a protective coating layer onto the heater. In one embodiment, the protective sealant coating layer has a thickness of 0.5 to about 4 mils. In yet another embodiment, the surface of the substrate to be sealed is first heated to at least of 150-200° C. prior to being coated with a layer of the glass ceramic composition.

In applications as an adhesive/coating layer or a sealant for heaters or wafer holder device, the composition provides protection at >400° C. in both oxidizing and reducing atmospheres over an extended period of time (10 hrs.) in a semi-conductor processing environment. Additionally, the filler composition accommodates stresses generated due to potential CTE mismatches between the various heater components through hundreds of thermal cycles. In one embodiment for a paste application, the filler composition is first milled, forming “glass frit” with an average particle size of less than 100 mesh. In one embodiment, the glass frit has an average particle size of <80 mesh. In a second embodiment, of less than 60 mesh. In a third embodiment, of less than 40 mesh.

In one embodiment, the glass frit is first mixed with a metal oxide powder (in solution) in a ratio of 80:20 to 95:5 glass frit to metal oxide. Examples of metal oxide include but not limited to aluminum oxide, magnesium oxide, calcium oxide, yttrium oxide, and zinc oxide. In one embodiment, the metal oxide is Al₂O₃ having an average particle size of about 0.05 μm. In a third embodiment, the glass frit is mixed with a metal oxide in a solution form, e.g., colloidal silica, colloidal alumina, colloidal yttria, colloidal zirconia, and mixtures thereof

In one embodiment, the mixture is blended in equipment known the art, e.g., a ball mill, with a carrier solution forming a slurry or paste in a ratio of 10-25 wt. % carrier solution to 75-90 wt. % of glass frit/metal oxide mixture. In one embodiment, the carrier solution is a mixture of distilled water with less than 1 wt. % nitric acid. In a second embodiment, the carrier solution is a mixture of ethanol and distilled water. In a third embodiment, the carrier solution is LiOH.

### EXAMPLE 1

In the example, a glass was prepared from a homogeneous powder mixture from reagent grade raw materials in the amount of 45 wt % yttrium oxide, 20 wt % aluminum oxide, and 35 wt % silicon dioxide. The powder mixture was melted in a platinum crucible at 1400° C. for 1 hr. The glass melt was poured into a steel mold and annealed from 680° C. to room temperature in 12 h. Each glass was crushed and milled in propanol using a mill with Al₂O₃ elements, forming a glass grit composition having an average particle size of 100 μm.

In the next step, the glass grit was added to a colloidal alumina solution in an amount of 75 wt. % glass grit and 25 wt. % colloidal alumina, forming a glass-ceramic adhesive paint/adhesive. The colloidal alumina solution is commercially available as Nyacol® AL20DW from Nycaol Nano Technologies, containing 20-25 wt. Al₂O₃, <1 wt. % nitric acid in 75-79 wt. % distilled water. In applications, the paste is heated >1000° C. to form an etch resistant layer protecting the underlying components. The high temperature allows the paste to form a seal on contact surfaces including but not limited to functional members, lead, fasteners such as nuts, bolts, rivets, etc.

### EXAMPLE 2

An electrically conductive heating element (molybdenum manganese) was deposited onto a ceramic substrate (AlN). The substrate contained through-holes to allow for installation of electrical contacts. In the next step, Ni-plated molybdenum posts were installed using molybdenum fasteners. The adhesive of Example 1 was painted around the contact points between the Ni-plated molybdenum posts, the molybdenum fasteners, heating element on the AlN substrate, and the AlN substrate. Next, the entire heater assembly including the contact was coated with AlN through a CVD process.

In a test simulating conditions of a heater with AlN substrate in a semiconductor processing environment, corrosion testing of the heater and contact was conducted after 100 thermal cycles between 400 and 500° C. at a ramp rate of 45° C./min. In another test, a heater with graphite core was cycled 100 times between 400 and 600° C. with a ramp rate of 60° C./min. The tests were to determine whether the glass ceramic adhesive would perform sufficiently under thermal stresses. After 100 thermal cycles, visual inspection showed that the heater coatings had no signs of failure due to thermal stresses, indicating that the CTE of the components was sufficiently matched, including that of the glass ceramic adhesive to protect the heater coatings.

Additionally, the heaters were installed in a vacuum chamber and brought to a pressure of approximately 1 millitorr. Power was then applied to the heater until the heater achieved 400° C. Once at 400° C., the heater was exposed to a fluorine/argon plasma for 10 hours. The plasma was generated using 400 sccm (standard cubic centimeters) of NF₃ gas and 1200 sccm of Ar gas. The chamber pressure during testing was 2.8 torr.

There was not significant electrical resistance change (<0.4%) observed on both of the heaters during the 10-hour etching process. The heaters were removed from the chamber and visually observed after 10 hrs. There was no failure of the AlN coating around the contact fasteners. There was no failure of the contact points between and within the electrical contact assembly and the heater. The glass ceramic adhesive functioned as an excellent sealant material for the heater of the invention.

### EXAMPLE 3

A filler composition comprising a powder mixture from reagent grade raw materials in the amount of 45 wt % yttrium oxide, 20 wt % aluminum oxide, 35 wt % silicon dioxide was compared with other materials known in the art, including alumina, molybdenum, TaC, AlN, graphite, and nickel. In the test, a) dimensions and mass of the sample was measured prior to testing; b) parts were placed in a vacuum chamber, which is then pumped down to a pressure of approximately 1 millitorr; c) the parts were heated to the desired testing temperature; d) a fluorine/argon plasma was generated above parts for the desired time period; e) after testing, the parts were removed from the chamber and the mass after exposure was recorded. The corrosion rate is calculated as follows:

corrosion rate=mass loss/density/exposed surface area/time;

wherein a negative corrosion rates indicate mass gain after exposure, which translates to excellent corrosion resistance.

The results of the experiments comparing YAS filler composition with other materials are as follows. Mo data is generally available from scientific references.

| | | | | Exposed | | | | |
|---|---|---|---|---|---|---|---|---|
| | Sample | | | Surface | | Exposure | Exposure | Corrosion |
| | Dimensions | Initial | Density | Area | Wt Loss | Temperature | Time | Rate |
| Material | (cm) | Mass (g) | (g/cc) | (cm²) | (grams) | (degrees C.) | (minutes) | (A°/minute) |
| YAS | 2.47 × 2.47 × 0.21 | 3.38751 | 8.59 | 4.78 | −8.00E−05 | 400 | 300 | −1 |
| Alumina | 2.535 dia. × 0.1 | 6.40293 | 3.69 | 5.05 | −1.00E−05 | 400 | 300 | −0.2 |
| | thk | | | | | | | |
| Mo | N/A | N/A | 10.28 | N/A | N/A | r.t. | N/A | 2490 |
| TaC | N/A | | | | | | | Poor |
| AIN | 3.2 dia. × 0.1 | 3.41162 | 3.26 | 8.1 | −4.00E−05 | 400 | 300 | −1 |
| | thk | | | | | | | |
| Graphite | 13.87 dia. × 0.5 | 117.0842 | 2.2 | 151 | −0.0075 | 400 | 300 | −2 |
| | thk | | | | | | | |
| Nickel | 5.0 × 5.0 × 0.04 | 11.30241 | 8.91 | 24.7 | 0.00225 | 400 | 300 | −3 |

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims. All citations referred herein are expressly incorporated herein by reference.

1. A processing apparatus for use in a processing chamber, the apparatus comprising:
a base substrate for placing a wafer thereon, the base substrate has a coefficient of thermal expansion (CTE);
at least one electrical electrode embedded in or disposed on at least a surface of the base substrate, the electrode is selected from a resistive heating electrode, a plasma-generating electrode, an electrostatic chuck electrode, and an electron-beam electrode, the electrode has a coefficient of thermal expansion (CTE) in a range of 0.75 to 1.25 times that of the base substrate CTE;
at least a functional member selected from the group of electrical leads, tabs, inserts, and through-holes, wherein the at least a functional member penetrates the wafer processing apparatus at an interval therefrom, creating a gap;
and a filler for sealing the gap in the wafer processing apparatus,
wherein the filler has an etch-rate of less than 1000 Angstroms per minute (Å/min) when the apparatus is exposed to an operating environment at a temperature range of 25-600° C., the environment is one of: an environment comprising halogens, a plasma etching environment, a reactive ion etching environment, a plasma cleaning environment, and a gas cleaning environment and an operating.

2. The processing apparatus of claim 1, wherein the filler has an etch-rate of less than 1000 Angstroms per minute (Å/min) and the environment is operated in a temperature range of 200-600° C.

3. The processing apparatus of claim 1, wherein the filler has an etch-rate of less than 500 Angstroms per minute (Å/min) and the environment is operated in a temperature range of 200-600° C.

4. The processing apparatus of claim 1, wherein the filler comprises a composition selected from the group of: a high thermal stability zirconium phosphate having an NZP structure of NaZr₂ (PO₄)₃; a glass-ceramic composition containing at least one element selected from the group consisting of elements of the group 2a, group 3a and group 4a; a BaO—Al₂O₃—B₂O₃—SiO₂ glass; and a mixture of SiO₂ and a plasma-resistant material comprising an oxide of Y, Sc, La, Ce, Gd, Eu, Dy, or the like, or a fluoride of one of these metals, or yttrium-aluminum-garnet (YAG).

5. The processing apparatus of claim 1, wherein the filer is a glass-ceramic composition selected from the group of lanthanum aluminosilicate (LAS) glass, magnesium aluminosilicate (MAS) glass, calcium aluminosilicate (CAS) glass, yttrium aluminosilicate (YAS) glass, and mixtures thereof.

6. The processing apparatus of claim 5, wherein the filler composition comprises a mixture of yttrium aluminosilicate (YAS) and a metal oxide powder.

7. The processing apparatus of claim 6, wherein metal oxide powder is selected from the group of aluminum oxide, magnesium oxide, calcium oxide and zinc oxide.

8. The processing apparatus of claim 1, wherein the filler comprises a mixture of yttrium aluminosilicate (YAS) and at least one of: colloidal silica, colloidal alumina, colloidal yttria, colloidal zirconia, and mixtures thereof.

9. The processing apparatus of claim 8, wherein the filler comprises from 50 to 80 wt. % of a glass composition comprising 25-55 wt. % Y₂O₃, 13 to 35 wt. % Al₂O₃, and 25 to 55 wt. % SiO₂; and from 20 to 50 wt. % of a colloidal alumina having a composition of 20 -25 wt. Al₂O₃, <1 wt. % nitric acid, and 75-79 wt. % distilled water.

10. The processing apparatus of claim 1, wherein the filler sealing the gap has a CTE in a range of 0.75 to 1.25 times that of the electrode CTE.

11. The processing apparatus of claim 1, wherein the base substrate comprises an electrically conducting material selected from the group of graphite, refractory metals, transition metals, rare earth metals and alloys thereof, and wherein

12. The processing apparatus of claim 11, further comprising at least an electrically insulating coating layer disposed on the base substrate, the coating layer comprising at least one of a nitride, carbide, carbonitride, oxynitride of elements selected from a group consisting of B, Al, Si, Ga, Y, refractory hard metals, transition metals, and combinations thereof.

13. The processing apparatus of claim 12, wherein the electrode is a film electrode, and wherein the film electrode is disposed on the electrically insulating coating layer by at least one of expanding thermal plasma (ETP), chemical vapor deposition (CVD), plasma enhanced chemical vapor deposition, ion plasma deposition, metal organic chemical vapor deposition, metal organic vapor phase epitaxy, sputtering, electron beam and plasma spray.

14. The processing apparatus of claim 1, wherein the base substrate is an electrically insulating material selected from the group of oxides, nitrides, carbides, carbonitrides or oxynitrides of elements selected from a group consisting of B, Al, Si, Ga, Y; a high thermal stability zirconium phosphate having an NZP structure of NaZr₂ (PO₄)₃; refractory hard metals; transition metals; oxide, oxynitride of aluminum, and combinations thereof.

15. The processing apparatus of claim 1, wherein the electrode is embedded in the base substrate.

16. The processing apparatus of claim 1, wherein the at least one electrical electrode is a resistive heating electrode.

17. The processing apparatus of claim 1, wherein the at least one electrical electrode is an electrostatic chuck.

18. A wafer processing apparatus for use in a semiconductor processing chamber, the apparatus comprising:
a base substrate for placing a wafer thereon, the base substrate has a coefficient of thermal expansion (CTE),
at least one electrode embedded in or disposed under the base substrate, selected from a resistive heating electrode, a plasma-generating electrode, an electrostatic chuck electrode, and an electron-beam electrode, the electrode has a coefficient of thermal expansion (CTE) in a range of 0.75 to 1.25 times that of the base substrate CTE;
at least a coating layer disposed on the base substrate, the coating layer comprising at least one of a nitride, carbide, carbonitride, oxynitride of elements selected from a group consisting of B, Al, Si, Ga, Y, refractory hard metals, transition metals, and combinations thereof.
at least a functional member selected from the group of electrical leads, tabs, inserts, and through-holes, wherein the at least a functional member penetrates the wafer processing apparatus at an interval therefrom, creating a gap;
and a filler for sealing the gap in the wafer processing apparatus, wherein the filler has an etch-rate of less than 1000 Angstroms per minute (Å/min) when the apparatus is exposed to an operating environment at a temperature range of 25-600° C. selected from one of: an environment comprising halogens, a plasma etching environment, a reactive ion etching environment, a plasma cleaning environment, and a gas cleaning environment and an operating.

19. A wafer processing apparatus for use in a semiconductor processing chamber, the apparatus comprising:
a base substrate for placing a wafer thereon, the base substrate has a coefficient of thermal expansion (CTE), the base substrate comprising an electrically insulating material selected from the group of oxides, nitrides, carbides, carbonitrides or oxynitrides of elements selected from a group consisting of B, Al, Si, Ga, Y; a high thermal stability zirconium phosphate having an NZP structure of NaZr₂ (PO₄)₃; refractory hard metals; transition metals; oxide, oxynitride of aluminum, and combinations thereof.
at least one electrode embedded in or disposed under the base substrate, selected from a resistive heating electrode, a plasma-generating electrode, an electrostatic chuck electrode, and an electron-beam electrode, the electrode has a coefficient of thermal expansion (CTE) in a range of 0.75 to 1.25 times that of the base substrate CTE;
at least a coating layer disposed on the base substrate, the coating layer comprising at least one of a nitride, carbide, carbonitride, oxynitride of elements selected from a group consisting of B, Al, Si, Ga, Y, refractory hard metals, transition metals, and combinations thereof,
at least a functional member selected from the group of electrical leads, tabs, inserts, and through-holes, wherein the at least a functional member penetrates the wafer processing apparatus at an interval therefrom, creating a gap;
and a filler for sealing the gap in the wafer processing apparatus,
wherein the filler comprises a composition selected from the group of: a high thermal stability zirconium phosphate having an NZP structure of NaZr₂ (PO₄)₃; a glass-ceramic composition containing at least one element selected from the group consisting of elements of the group 2a, group 3a and group 4a; a BaO—Al₂O₃—B₂O₃—SiO₂ glass; and a mixture of SiO₂ and a plasma-resistant material comprising an oxide of Y, Sc, La, Ce, Gd, Eu, Dy, or the like, or a fluoride of one of these metals, or yttrium-aluminum-garnet (YAG);
the filler has an etch-rate of less than 1000 Angstroms per minute (Å/min) when the apparatus is exposed to an operating environment at a temperature range of 25-600° C. selected from one of: an environment comprising halogens, a plasma etching environment, a reactive ion etching environment, a plasma cleaning environment, and a gas cleaning environment and an operating.

20. The wafer processing apparatus of claim 19, wherein the functional member is an electrical lead, and the gap is created by the lead for connecting the electrode to an external power supply.
